(19) United States
(12) Patent Application Publication
(10) Pub. No.: US 2025/0246225 A1
(43) Pub. Date: Jul. 31, 2025

(54) CLOCK AMPLIFIER CIRCUIT AND MEMORY DEVICE INCLUDING THE SAME

(71) Applicant: Samsung Electronics Co., Ltd., Suwon-si (KR)

(72) Inventors: Cheolmin Ahn, Suwon-si (KR); Yonghun Kim, Suwon-si (KR); Kihan Kim, Suwon-si (KR); SEOKHUN HYUN, Suwon-si (KR)

(21) Appl. No.: 18/819,021

(22) Filed: Aug. 29, 2024

(30) Foreign Application Priority Data
Jan. 29, 2024 (KR) 10-2024-0013355

(51) Int. Cl. G11C 11/4076; G11C 11/4096; H03F 3/45; H03G 3/30

(52) U.S. Cl. CPC G11C 11/4076; G11C 11/4096; H03F 3/45192; H03G 3/30; H03F 2203/45022; H03F 2203/45028

(57) ABSTRACT

A memory device including a memory cell array, an input/output circuit receiving data to be stored in the memory cell array based on a write clock signal received from an external device during a write operation, and a clock amplifier circuit providing an internal clock signal to the input/output circuit by amplify the write clock signal and including a folded cascode amplifier which amplifies the write clock signal. The folded cascode amplifier amplifies the write clock signal according to a gain between an input unit and an output unit, and includes a gain adjustment unit which is connected to the output unit and increases the gain between the input unit and the output unit based on the write clock signal.

### CROSS-REFERENCE TO RELATED APPLICATIONS

This application claims priority under 35 U.S.C. § 119 to Korean Patent Application No. 10-2024-0013355 filed on Jan. 29, 2024, in the Korean Intellectual Property Office, the disclosure of which is incorporated by reference herein in its entirety.

### BACKGROUND

### 1. Field

Example embodiments of the present disclosure described herein relate to a semiconductor memory device, and more particularly, relate to a clock amplifier circuit and a memory device including the same.

### 2. Description of Related Art

A semiconductor memory may be mainly classified as a volatile memory or a non-volatile memory. Read and write speeds of the volatile memory (for example, a DRAM or an SRAM) are fast, but the data stored in the volatile memory disappear when a power is turned off. In contrast, the non-volatile memory may retain data even when the power is turned off. Therefore, the non-volatile memory may be used to store contents that must be preserved regardless of whether power is supplied or not.

A representative example of a volatile memory device is a DRAM. A memory cell of a volatile memory device may include a single N-type transistor, serving as a switch, and a single capacitor storing electric charges DATA. Binary information “1” or “0” may correspond to the presence or absence of the electric charges stored in the capacitor in the memory cell, for example, whether a terminal voltage of a cell capacitor is high or low. The memory cell may be connected to a wordline and a bitline. The bitline may be connected to a sense amplifier. The sense amplifier may sense data, stored in the memory cell, through the bitline based on a voltage applied to the wordline.

The volatile memory device may receive or transmit data from or to a memory controller through an input/output circuit. The volatile memory device may receive a write clock signal from the memory controller during a write operation. The input/output circuit of the volatile memory device may receive data based on the write clock signal during the write operation. However, the write clock signal is declining during a transmission process and needs to be amplified inside the volatile memory device.

### SUMMARY

Example embodiments of the present disclosure provide a clock amplifier circuit adjusting a gain based on a write clock signal when amplifying the write clock signal received from a memory controller during a write operation and a memory device including the same.

According to an embodiment, a memory device including: a memory cell array; an input/output circuit receiving data to be stored in the memory cell array based on a write clock signal received from an external device during a write operation; and a clock amplifier circuit providing an internal clock signal to the input/output circuit by amplify the write clock signal and including a folded cascode amplifier which amplifies the write clock signal. The folded cascode amplifier amplifies the write clock signal according to a gain between an input unit and an output unit, and includes a gain adjustment unit which is connected to the output unit and increases the gain between the input unit and the output unit based on the write clock signal.

According to an embodiment, a folded cascode amplifier circuit including: a differential input unit receiving a first differential input signal and a second differential input signal which are complementary to each other, and outputting a first differential current signal in which the first differential input signal is inverted and a second differential current signal in which the second differential input signal is inverted based on a first current source; a differential output unit outputting a first differential amplified signal in response to the first differential current signal and outputting a second differential amplified signal in response to the second differential current signal; and a gain adjustment unit determining a gain between the first differential input signal and the first differential amplified signal based on the second differential current signal, and determining a gain between the second differential input signal and the second differential amplified signal based on the first differential current signal.

According to an embodiment, a folded cascode amplifier circuit including: a first differential amplification unit receiving a first differential input signal and outputting a first differential amplified signal which is inverted and amplified from the first differential input signal; a second differential amplification unit receiving a second differential input signal complementary to the first differential input signal and outputting a second differential amplified signal which is inverted and amplified from the second differential input signal; a first DC gain adjustment unit increasing a DC gain of the first differential amplification unit based on the second differential input signal; a second DC gain adjustment unit increasing a DC gain of the second differential amplification unit based on the first differential input signal; a first AC gain adjustment unit increasing an AC gain of the first differential amplification unit based on the first differential input signal; and a second AC gain adjustment unit increasing an AC gain of the second differential amplification unit based on the second differential input signal.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a memory system according to an example embodiment.

FIG. 2 is a block diagram illustrating a memory device of FIG. 1.

FIG. 3 is a block diagram illustrating an example embodiment of a clock amplifier circuit of FIG. 2.

FIG. 4 is a circuit diagram illustrating an example embodiment of a folded cascode amplifier of FIG. 3.

FIG. 5 is a diagram illustrating an example embodiment of an amplification operation of a folded cascode amplifier of FIG. 4.

FIG. 6 is a circuit diagram illustrating another example of a folded cascode amplifier of FIG. 3.

FIG. 7 is a diagram illustrating an example embodiment of an amplification operation of a folded cascode amplifier of FIG. 6.

FIG. 8 is a diagram illustrating an example embodiment of a first main resistor and a first sub-resistor of FIG. 6.

FIG. 9 is a circuit diagram illustrating another example of a folded cascode amplifier of FIG. 3.

FIG. 10 is a diagram illustrating an example embodiment of an amplification operation of a folded cascode amplifier of FIG. 9.

FIG. 11 is a circuit diagram illustrating another example of a folded cascode amplifier of FIG. 3.

### DETAILED DESCRIPTION

Below, example embodiments of the present disclosure will be described in detail and clearly to such an extent that one of ordinary skill in the art may easily implement the inventive concepts.

Below, a DRAM will be used as an example for illustrating features and functions of the present disclosure. However, other features and performances may be easily understood from information disclosed herein by a person of ordinary skill in the art. The present disclosure may be implemented by other embodiments or applied thereto. Further, the detailed description may be modified or changed according to viewpoints and applications without escaping from the scope, spirit, and other objects of the present disclosure.

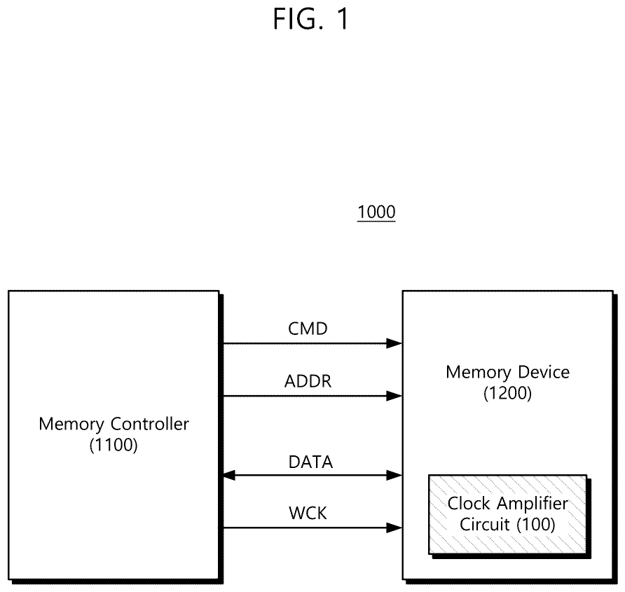

FIG. 1 is a block diagram illustrating a memory system according to an example embodiment. Referring to FIG. 1, a memory system 1000 may include a memory controller 1100 and a memory device 1200.

According to an example embodiment, the memory controller 1100 may perform an access operation of writing data to the memory device 1200 or reading data stored in the memory device 1200. For example, the memory controller 1100 may generate a command CMD and an address ADDR for writing data to the memory device 1200 or reading data stored in the memory device 1200. The memory controller 1100 may include at least one of a control circuit controlling the memory device 1200, a system-on-chip (SoC) such as an application processor (AP), a central processing unit (CPU), a digital signal processor (DSP), and a graphics processing unit (GPU).

According to an example embodiment, the memory controller 1100 may provide various signals to the memory device 1200 to control an overall operation of the memory device 1200. For example, the memory controller 1100 may control memory access operations of the memory device 1200 such as a read operation and a write operation. The memory controller 1100 may provide the command CMD and the address ADDR to the memory device 1200 to write data DATA in the memory device 1200 or to read data DATA from the memory device 1200.

According to an example embodiment, the memory controller 1100 may generate various types of commands CMD to control the memory device 1200. For example, the memory controller 1100 may generate a bank request corresponding to a bank operation of changing a state of a memory bank, among memory banks, to read or write data DATA.

As an example, the bank request may include an active request for changing a state of a memory bank, among the memory banks, to an active state. The memory device 1200 may activate a row included in the memory bank, for example, a wordline, in response to the active request. The bank request may include a precharge request for changing the memory banks from an active state to a standby state after reading or writing of data DATA is completed.

In addition, the memory controller 1100 may generate an input/output (I/O) request (for example, a column address strobe (CAS) request) for the memory device 1200 to perform a read operation or a write operation of data DATA. As an example, the I/O request may include a read request for reading data DATA from activated memory banks. The I/O request may include a write request for writing data DATA in the activated memory banks.

Furthermore, the memory controller 1100 may generate a refresh command to control a refresh operation on the memory banks. However, the types of commands CMD described herein are merely exemplary, and other types of commands CMD may be present.

According to an example embodiment, the memory device 1200 may output data DATA, requested to be read by the memory controller 1100, to the memory controller 1100 or may store data DATA, requested to be written by the memory controller 1100, in a memory cell of the memory device 1200. The memory device 1200 may input and output data DATA based on the command CMD and the address ADDR. The memory device 1200 may include memory banks.

The memory device 1200 may be a volatile memory device such as a dynamic random access memory (DRAM), a synchronous dynamic random access memory (SDRAM), a double data rate (DDR) DRAM, a DDR SDRAM, a low-power double data rate (LPDDR) SDRAM, a graphics double data rate (GDDR) SDRAM, a Rambus dynamic random access memory (RDRAM), and a static random access memory (SRAM), or the like. Alternatively, the memory device 1200 may be implemented as a nonvolatile memory device such as a resistive RAM (RRAM), a phase change memory (PRAM), a magnetoresistive memory (MRAM), a ferroelectric memory (FRAM), a spin-transfer torque RAM (STT-RAM), or the like. In the present specification, the advantages of the present disclosure have been described with respect to a DRAM, but example embodiments are not limited thereto.

According to an example embodiment, the memory banks may include a memory cell array divided in units of banks, a row decoder, a column decoder, a sense amplifier, a write driver, or the like. The memory banks may store data DATA, requested to be written in the memory device 1200, through the write driver and may read data DATA, requested to be read, using the sense amplifier. The memory banks may further include a component for a refresh operation of storing and maintaining data in the cell array, or select circuits based on an address.

According to an example embodiment, the memory device 1200 may include a clock amplifier circuit 100. For example, during a write operation, the memory device 1200 may receive a write clock signal WCK from the memory controller 1100. The clock amplifier circuit 100 may amplify the write clock signal WCK and output an internal write clock signal. An input/output circuit of the memory device 1200 may perform the write operation of data DATA received from the memory controller 1100 based on the internal write clock signal.

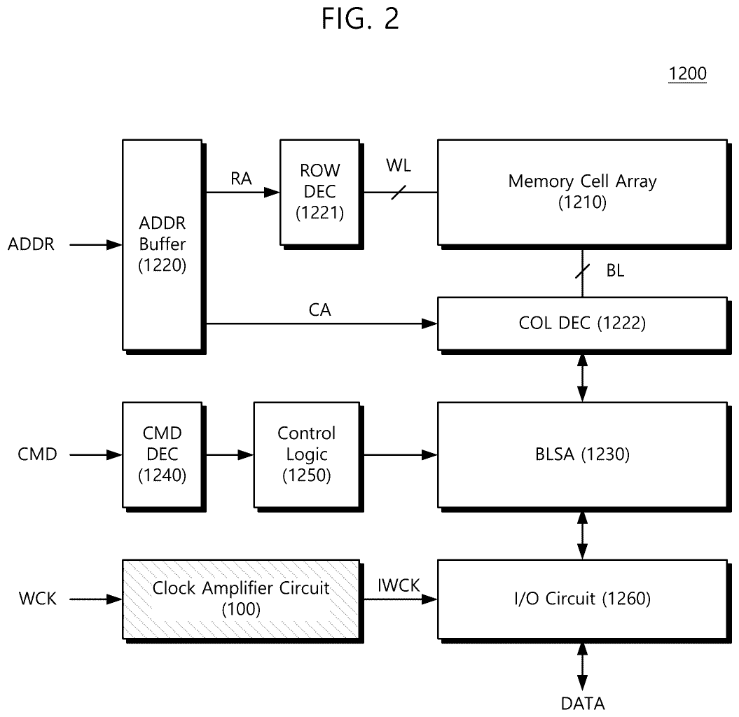

FIG. 2 is a block diagram illustrating a memory device of FIG. 1. Referring to FIG. 2, the memory device 1200 may include a memory cell array 1210, an address buffer 1220, a row decoder 1221, a column decoder 1222, a bitline sense amplifier 1230, a command decoder 1240, control logic 1250 and an input/output circuit 1260. In addition, the memory device 1200 may include a clock amplifier circuit 100.

According to an example embodiment, the memory cell array 1210 may include a plurality of memory cells arranged in a matrix of rows and columns. For example, the memory cell array 1210 may include a plurality of wordlines WL and a plurality of bitlines BL connected to memory cells. The plurality of wordlines WL may be connected to rows of the memory cells, and the plurality of bitlines BL may be connected to columns of the memory cells.

According to an example embodiment, the address buffer 1220 may receive an address ADDR from the memory controller 1100 of FIG. 1. For example, the address ADDR may include a row address RA addressing a row of the memory cell array 1210 and a column address CA addressing a column of the memory cell array 1210. The address buffer 1220 may transmit the row address RA to the row decoder 1221 and may transmit the column address CA to the column decoder 1222.

According to an example embodiment, the row decoder 1221 may select one of the plurality of wordlines WL connected to the memory cell array 1210. The row decoder 1221 may decode the row address RA, received from the address buffer 1220, to select a single wordline corresponding to the row address RA and may activate the selected wordline.

According to an example embodiment, the column decoder 1222 may select a predetermined bitline from among the plurality of bitlines BL of the memory cell array 1210. The column decoder 1222 may decode the column address CA, received from the address buffer 1220, to select the predetermined bitline BL corresponding to the column address CA.

According to an example embodiment, the bitline sense amplifier 1230 may be connected to the bitlines BL of the memory cell array 1210. For example, the bitline sense amplifier 1230 may sense a change in voltage of a selected bitline, among the plurality of bitlines BL, and may amplify and output the change in voltage.

According to an example embodiment, the command decoder 1240 may decode a write enable signal/WE, a row address strobe signal/RAS, a column address strobe signal/CAS, and a chip select signal/CS received from the memory controller 1100 such that control signals corresponding to the command CMD are generated in the control logic 1250. The command CMD may include an active request, a read request, a write request, or a precharge request.

According to an example embodiment, the control logic 1250 may control an overall operation of the bitline sense amplifier 1230 through the control signals corresponding to the command CMD. Additionally, the control logic 1250 may control an overall operation of the memory device 1200.

According to an example embodiment, the input/output circuit 1260 may output data DATA to the memory controller 1100 through data pad based on a sensed and amplified voltage from the bitline sense amplifier 1230. For example, the input/output circuit 1260 may include an input buffer or an output buffer. The input buffer or the output buffer may be connected to the data pad. The input/output circuit 1260 may perform a serialization operation or a deserialization operation of data DATA.

According to an example embodiment, the clock amplifier circuit 100 may amplify a write clock signal WCK and output an internal write clock signal IWCK. For example, during a write operation, the memory device 1200 may receive the write clock signal WCK from the memory controller 1100. The clock amplifier circuit 100 may amplify the write clock signal WCK which is declining during transmission from the memory controller 1100. Additionally, the clock amplifier circuit 100 may divide the write clock signal WCK to generate the internal write clock signal IWCK. The input/output circuit 1260 may transfer data DATA received from the memory controller 1100 to the bit line sense amplifier 1230 based on the internal write clock signal IWCK.

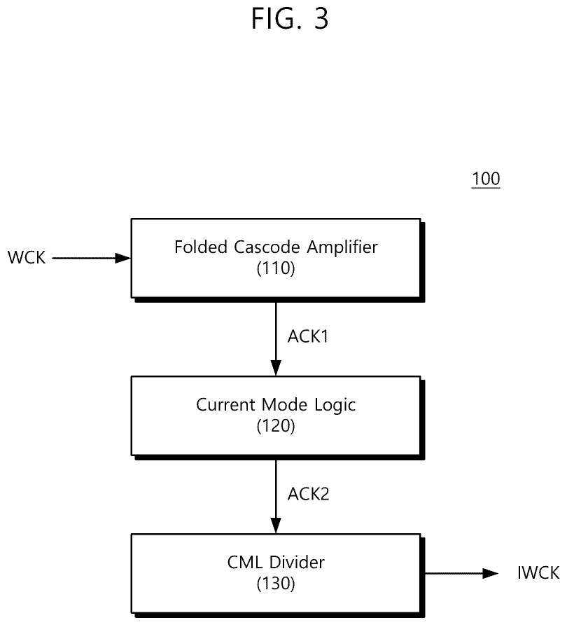

FIG. 3 is a block diagram illustrating an example embodiment of a clock amplifier circuit of FIG. 2. Referring to FIGS. 2 and 3, a clock amplifier circuit 100 may amplify a write clock signal WCK received from the memory controller 1100 of FIG. 1 and output an internal write clock signal IWCK. The clock amplifier circuit 100 may include a folded cascode amplifier 110, a current mode logic 120 and/or a current mode logic (CML) divider 130.

According to an example embodiment, the folded cascode amplifier 110 may amplify the write clock signal WCK and output the first amplified clock signal ACK1. The write clock signal WCK may decline while being transmitted from the memory controller 1100 to the memory device 1200. The folded cascode amplifier 110 may primarily amplify the write clock signal WCK.

According to an example embodiment, the current mode logic 120 may amplify the first amplified clock signal ACK1 and output a second amplified clock signal ACK2. The current mode logic 120 may secondarily amplify the first amplified clock signal ACK1 to a size required in the memory device 1200. Additionally, the current mode logic 120 may process the first amplified clock signal ACK1 so that a high level and a low level of the first amplified clock signal ACK1 are clearly distinguished.

According to an example embodiment, the CML divider 130 may change a frequency of the second amplified clock signal ACK2 to output the internal write clock signal IWCK. The CML divider 130 may divide the second amplified clock signal ACK2 to correspond to a frequency used in the input/output circuit 1260 during a write operation.

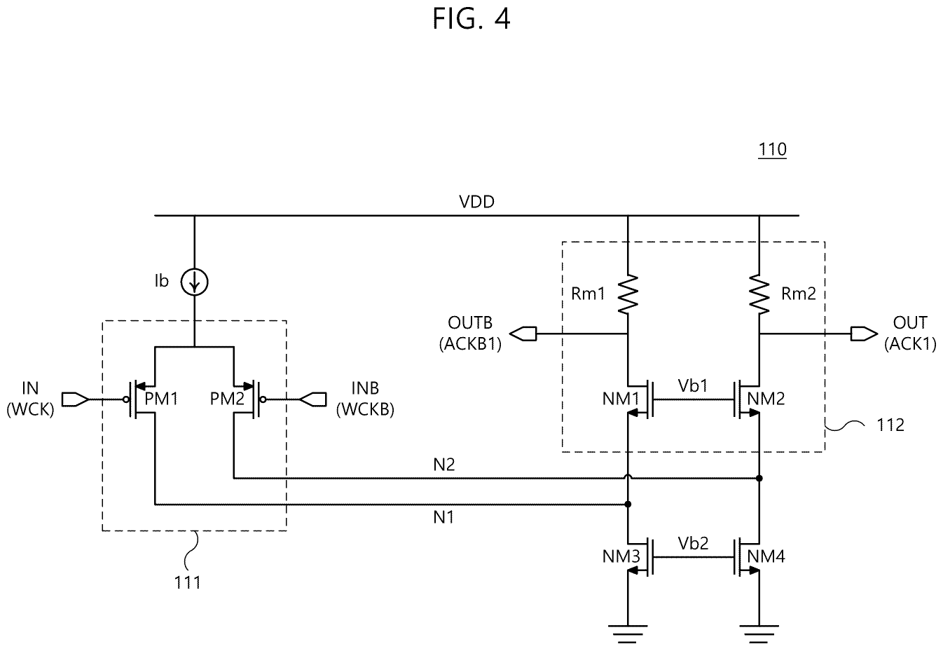

FIG. 4 is a circuit diagram illustrating an example embodiment of a folded cascode amplifier of FIG. 3. Referring to FIG. 4, the folded cascode amplifier 110 may include an input unit 111 and an output unit 112. The folded cascode amplifier 110 may amplify differential input signals (for example, a write clock signal WCK and a complementary write clock signal

WCKB) based on a specified gain between the input unit 111 and the output unit 112 to output differential output signals (for example, a first amplified clock signal ACK1 and a first complementary amplified clock signal ACKB1). The input unit 111 and the output unit 112 may include a mirror structure amplifying a pair of differential signals.

According to an example embodiment, the input unit 111 may include a first P-type transistor PM1 and a second P-type transistor PM2. For example, sources of the first P-type transistor PM1 and the second P-type transistor PM2 may be connected to a current source Ib. A gate of the first P-type transistor PM1 may be connected to an input terminal IN. A drain of the first P-type transistor PM1 may be connected to a first node N1. A gate of the second P-type transistor PM2 may be connected to a complementary input terminal INB. A drain of the second P-type transistor PM2 may be connected to a second node N2.

According to an example embodiment, the output unit 112 may include a first N-type transistor NM1 and a second N-type transistor NM2. For example, gates of the first N-type transistor NM1 and the second N-type transistor NM2 may be connected to a terminal of a first bias voltage Vb1. A drain of the first N-type transistor NM1 may be connected to a complementary output terminal OUTB. A source of the first N-type transistor NM1 may be connected to the first node N1. A drain of the second N-type transistor NM2 may be connected to an output terminal OUT. A source of the second N-type transistor NM2 may be connected to the second node N2.

In addition, the output unit 112 may include a first main resistor Rm1 and a second main resistor Rm2. For example, the first main resistor Rm1 may be connected between a terminal of a power supply voltage VDD and the complementary output terminal OUTB. The second main resistor Rm2 may be connected between the terminal of the power supply voltage VDD and the output terminal OUT.

According to an example embodiment, a third N-type transistor NM3 may operate as a current source of the first N-type transistor NM1. For example, a gate of the third N-type transistor NM3 may be connected to a terminal of a second bias voltage Vb2. A drain of the third N-type transistor NM3 may be connected to the first node N1. A source of the third N-type transistor NM3 may be connected to a ground terminal.

According to an example embodiment, a fourth N-type transistor NM4 may operate as a current source of the second N-type transistor NM2. For example, a gate of the fourth N-type transistor NM4 may be connected to the terminal of the second bias voltage Vb2. A drain of the fourth N-type transistor NM4 may be connected to the second node N2. A source of the fourth N-type transistor NM4 may be connected to the ground terminal.

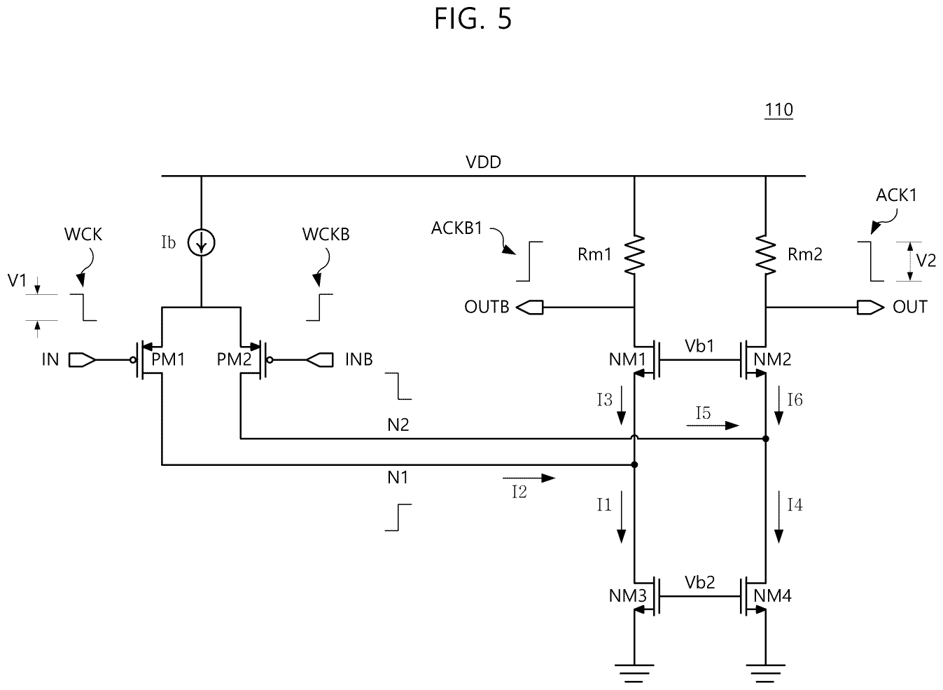

FIG. 5 is a diagram illustrating an example embodiment of an amplification operation of the folded cascode amplifier of FIG. 4. Referring to FIGS. 4 and 5, the folded cascode amplifier 110 may perform an amplification operation based on a specified gain between the input unit 111 and the output unit 112. As an example, differential input signals may be a write clock signal WCK and a complementary write clock signal WCKB. Differential output signals may be a first amplified clock signal ACK1 and a first complementary amplified clock signal ACKB1. Accordingly, input unit 111 may also be referred to as a differential input unit and output unit 112 may also be referred to as a differential output unit.

According to an example embodiment, in the first node N1, a first current I1 may be determined by the third N-type transistor NM3. A second current 12 may be determined by the first P-type transistor PM1. A third current I3 may be determined by difference between the first current I1 and the second current I2.

According to an example embodiment, in the second node N2, a fourth current I4 may be determined by the fourth N-type transistor NM4. A fifth current I5 may be determined by the second P-type transistor PM2. A sixth current I6 may be determined by difference between the fourth current I4 and the fifth current I5.

According to an example embodiment, the write clock signal WCK may be input to the input terminal IN. The complementary write clock signal WCKB may be input to the complementary input terminal INB. For example, the write clock signal WCK and the complementary write clock signal WCKB may have a first voltage amplitude V1. In FIG. 5, the write clock signal WCK is switched from a high level to a low level, and the complementary write clock signal WCKB is switched from a low level to a high level.

According to an example embodiment, when the write clock signal WCK which switches from a high level to a low level is input, the first P-type transistor PM1 may be gradually turned on, and the second current 12 may have a waveform which is complementary to a waveform of the write clock signal WCK. Accordingly, in response to an increase in the second current I2, the third current I3 may have a decreasing waveform. Since the third current I3 flowing through the first main resistor Rm1 decreases, the complementary output terminal OUTB may output the first complementary amplified clock signal ACKB1 which switches from a low level to a high level.

According to an example embodiment, the first complementary amplified clock signal ACKB1 may have a second voltage amplitude V2 greater than the first voltage amplitude V1. The second voltage amplitude V2 may be determined by a gain between the first P-type transistor PM1 and the first N-type transistor NM1. Additionally, since the first N-type transistor NM1 is turned on by the fixed first bias voltage Vb1, the second voltage amplitude V2 may be determined by the fixed gain.

According to an example embodiment, when the complementary write clock signal WCKB which switches from a low level to a high level is input, the second P-type transistor PM2 may be gradually turned off, and the fifth current I5 may have a waveform which is complementary to a waveform of the complementary write clock signal WCKB. Accordingly, in response to a decrease in the fifth current I5, the sixth current I6 may have an increasing waveform. Since the sixth current I6 flowing through the second main resistor Rm2 increases, the output terminal OUT may output the first amplified clock signal ACK1 which switches from a high level to a low level.

According to an example embodiment, the first amplified clock signal ACK1 may have the second voltage amplitude V2 greater than the first voltage amplitude V1. The second voltage amplitude V2 may be determined by a gain between the second P-type transistor PM2 and the second N-type transistor NM2. Additionally, since the second N-type transistor NM2 is turned on by the fixed first bias voltage Vb1, the second voltage amplitude V2 may be determined by the fixed gain.

However, the folded cascode amplifier 110 of FIGS. 4 and 5 may have a fixed gain between the input unit 111 and the output unit 112, and when the size of the input signals (for example, the write clock signal WCK and the complementary write clock WCKB) decreases, the size of the output signals (for example, the first amplified clock signal ACK1 and the first complementary amplified clock signal ACKB1) may also decrease at the same rate. Accordingly, the second amplified clock signal ACK2 output by the current mode logic 120 may also decrease, and an error may occur in the CML divider 130 of FIG. 3.

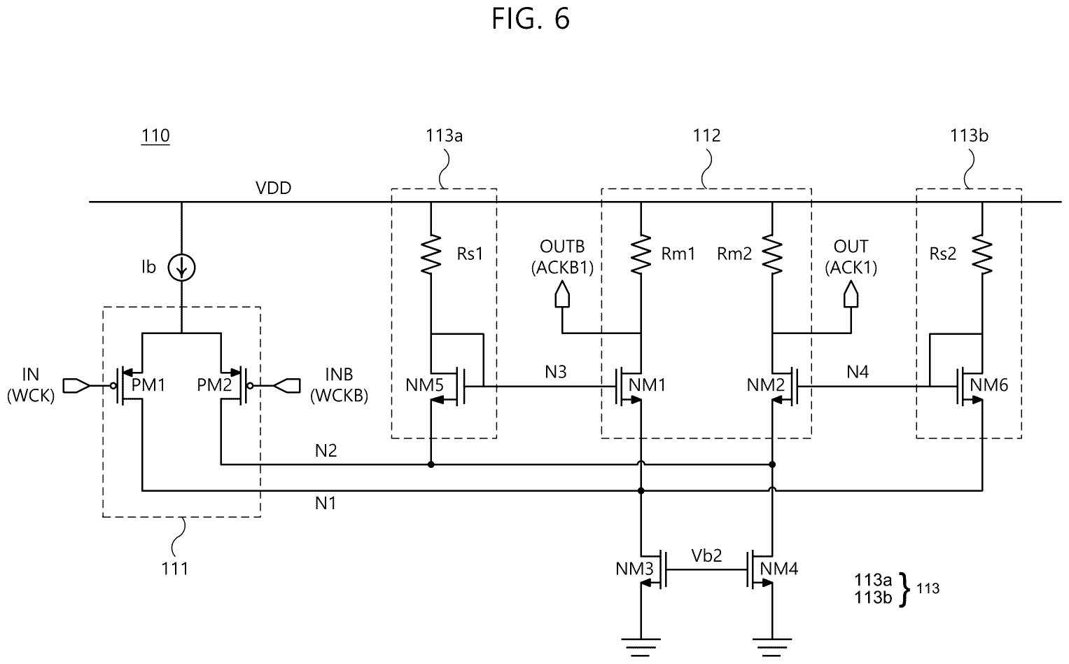

FIG. 6 is a circuit diagram illustrating another example of a folded cascode amplifier of FIG. 3. Referring to FIG. 6, the folded cascode amplifier 110 may include an input unit 111 and an output unit 112. The folded cascode amplifier 110 may further include a gain adjustment unit 113. The gain adjustment unit 113 may include a first gain adjustment unit 113a and a second gain adjustment unit 113b.

According to an example embodiment, the folded cascode amplifier 110 may amplify input signals (for example, a write clock signal WCK and a complementary write clock signal WCKB) based on a gain between the input unit 111 and the output unit 112 to output output signals (for example, a first amplified clock signal ACK1 and a first complementary amplified clock signal ACKB1). The gain between the input unit 111 and the output unit 112 may be changed based on magnitude of the input signals.

According to an example embodiment, the input unit 111 may include a first P-type transistor PM1 and a second P-type transistor PM2. For example, sources of the first P-type transistor PM1 and the second P-type transistor PM2 may be connected to a current source Ib. A gate of the first P-type transistor PM1 may be connected to an input terminal IN. A drain of the first P-type transistor PM1 may be connected to a first node N1. A gate of the second P-type transistor PM2 may be connected to a complementary input terminal INB. A drain of the second P-type transistor PM2 may be connected to a second node N2.

According to an example embodiment, the output unit 112 may include a first N-type transistor NM1. For example, a drain of the first N-type transistor NM1 may be connected to a complementary output terminal OUTB. A source of the first N-type transistor NM1 may be connected to the first node N1. A gate of the first N-type transistor NM1 may be connected to a third node N3.

Additionally, the output unit 112 may include a second N-type transistor NM2. For example, a drain of the second N-type transistor NM2 may be connected to an output terminal OUT. A source of the second N-type transistor NM2 may be connected to the second node N2. A gate of the second N-type transistor NM2 may be connected to a fourth node N4.

Furthermore, the output unit 112 may include a first main resistor Rm1 and a second main resistor Rm2. For example, the first main resistor Rm1 may be connected between a terminal of the power supply voltage VDD and the complementary output terminal OUTB. The second main resistor Rm2 may be connected between the terminal of the power supply voltage VDD and the output terminal OUT. The first P-type transistor PM1, the first N-type transistor NM1, and the first main resistor Rm1 may collectively be referred to as a first differential amplification unit herein. The second P-type transistor PM2, the second N-type transistor NM2, and second main resistor Rm2 may collectively be referred to as a second differential amplification unit herein.

According to an example embodiment, the first gain adjustment unit 113a may include a fifth N-type transistor NM5 and a first sub-resistor Rs1. For example, a gate and drain of the fifth N-type transistor NM5 may be connected to the third node N3. A source of the fifth N-type transistor NM5 may be connected to the second node N2. The first sub-resistor Rs1 may be connected between the terminal of the power supply voltage VDD and the third node N3.

According to an example embodiment, the second gain adjustment unit 113b may include a sixth N-type transistor NM6 and a second sub-resistor Rs2. For example, a gate and a drain of the sixth N-type transistor NM6 may be connected to the fourth node N4. A source of the sixth N-type transistor NM6 may be connected to the first node N1. The second sub-resistor Rs2 may be connected between the terminal of the power supply voltage VDD and the fourth node N4. The first gain adjustment unit 113a may also be referred to as a first DC gain adjustment unit herein. The second gain adjustment unit 113b may also be referred to as a second DC gain adjustment unit herein.

According to an example embodiment, the third N-type transistor NM3 may operate as a current source of the first N-type transistor NM1. For example, the gate of the third N-type transistor NM3 may be connected to a terminal of a second bias voltage Vb2. The drain of the third N-type transistor NM3 may be connected to the first node N1. The source of the third N-type transistor NM3 may be connected to a ground terminal.

According to an example embodiment, the fourth N-type transistor NM4 may operate as a current source of the second N-type transistor NM2. For example, the gate of the fourth N-type transistor NM4 may be connected to a terminal of a second bias voltage Vb2. The drain of the fourth N-type transistor NM4 may be connected to the second node N2. The source of the fourth N-type transistor NM4 may be connected to the ground terminal.

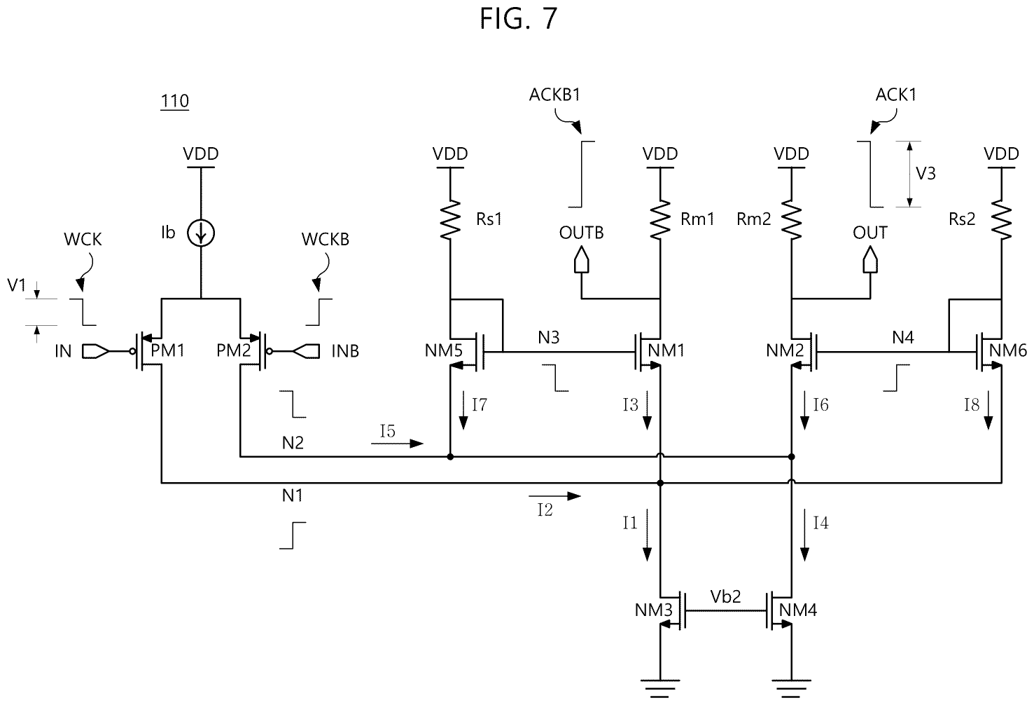

FIG. 7 is a diagram illustrating an example embodiment of an amplification operation of a folded cascode amplifier of FIG. 6. Referring to FIGS. 6 and 7, the folded cascode amplifier 110 may perform an amplification operation based on a gain between the input unit 111 and the output unit 112. The gain between the input unit 111 and the output unit 112 may be changed based on a magnitude of the input signals. As an example, differential input signals may be a write clock signal WCK and a complementary write clock signal WCKB. Differential output signals may be a first amplified clock signal ACK1 and a first complementary amplified clock signal ACKB1.

According to an example embodiment, in the first node N1, a first current I1 may be determined by the third N-type transistor NM3. A second current I2 may be determined by the first P-type transistor PM1. A third current I3 and an eighth current I8 may be determined by difference between the first current I1 and the second current I2.

According to an example embodiment, in the second node N2, a fourth current I4 may be determined by the fourth N-type transistor NM4. A fifth current I5 may be determined by the second P-type transistor PM2. A sixth current I6 and a seventh current I7 may be determined by difference between the fourth current I4 and the fifth current I5.

According to an example embodiment, the write clock signal WCK may be input to the input terminal IN. The complementary write clock signal WCKB may be input to the complementary input terminal INB. For example, the write clock signal WCK and the complementary write clock signal WCKB may have a first voltage amplitude V1. In FIG. 7, the write clock signal WCK may be switched from a high level to a low level, and the complementary write clock signal WCKB may be switched from a low level to a high level.

According to an example embodiment, when the write clock signal WCK which switches from a high level to a low level is input, the first P-type transistor PM1 may be gradually turned on, and the second current I2 may have a waveform which is complementary to a waveform of the write clock signal WCK. Accordingly, in response to an increase in the second current I2, the third current I3 and the eighth current I8 may have a decreasing waveform. Since the third current I3 flowing through the first main resistor Rm1 decreases, the complementary output terminal OUTB may output the first complementary amplified clock signal ACKB1 which switches from a low level to a high level.

According to an example embodiment, the first gain adjustment unit 113a may increase a gain of an amplifier including the first P-type transistor PM1 and the first N-type transistor NM1 based on a signal of the complementary input terminal INB. For example, when the write clock signal WCK switches from a high level to a low level, the complementary write clock signal WCKB may switch from a low level to a high level, and the fifth current 15 flowing through the second P-type transistor PM2 may be reduced. When the fifth current 15 decreases, the seventh current I7 flowing through the fifth N-type transistor NM5 and/or the first sub-resistor Rs1 may increase, and a voltage level of the third node N3 may decrease. Accordingly, voltage difference between the gate and the source of the first N-type transistor NM1 may decrease, and the third current I3 flowing through the first N-type transistor NM1 and/or the first main resistor Rm1 may further decrease.

Accordingly, the first complementary amplified clock signal ACKB1 may have a third voltage amplitude V3 greater than the second voltage amplitude V2 of FIG. 5. A gate voltage of the first N-type transistor NM1 may change in response to the complementary write clock signal WCKB, and a gain of an amplifier including the first P-type transistor PM1 and the first N-type transistor NM1 may be increased from the gain illustrated in FIG. 5.

According to an example embodiment, when the complementary write clock signal WCKB which switches from a low level to a high level is input, the second P-type transistor PM2 may be gradually turned off, and the fifth current I5 may have a waveform which is complementary to a waveform of the complementary write clock signal WCKB. Accordingly, in response to a decrease in the fifth current I5, the sixth current I6 and the seventh current I7 may have increasing waveforms. Since the sixth current 16 flowing through the second main resistor Rm2 increases, the output terminal OUT may output the first amplified clock signal ACK1 which switches from a high level to a low level.

According to an example embodiment, the second gain adjustment unit 113b may increase a gain of an amplifier including the second P-type transistor PM2 and the second N-type transistor NM2 based on the signal from the input terminal IN. For example, when the complementary write clock signal WCKB switches from a low level to a high level, the write clock signal WCK may switch from a high level to a low level, and the second current I2 flowing through the first P-type transistor PM1 may increase. When the second current I2 increases, the eighth current 18 flowing through the sixth N-type transistor NM6 and the second sub-resistor Rs2 may decrease, and a voltage level of the fourth node N4 may increase. At this time, voltage difference between the gate and the source of the second N-type transistor NM2 may increase, and the sixth current 16 flowing through the second N-type transistor NM2 and the second main resistor Rm2 may further increase.

Accordingly, the first amplified clock signal ACK1 may have the third voltage amplitude V3 greater than the second voltage amplitude V2 of FIG. 5. A gate voltage of the second N-type transistor NM2 may change in response to the write clock signal WCK, and a gain of an amplifier including the second P-type transistor PM2 and the second N-type transistor NM2 may increase from the gain illustrated in FIG. 5.

According to an example embodiment, a gain of the folded cascode amplifier 110 may be determined based on a ratio of the main resistance and the sub-resistor. For example, a gain of an amplifier including the first P-type transistor PM1 and the first N-type transistor NM1 may be determined according to a ratio of the first main resistor Rm1 and the first sub-resistor Rs1. A gain of an amplifier including the second P-type transistor PM2 and the second N-type transistor NM2 may be determined according to a ratio of the second main resistance Rm2 and the second sub-resistor Rs2.

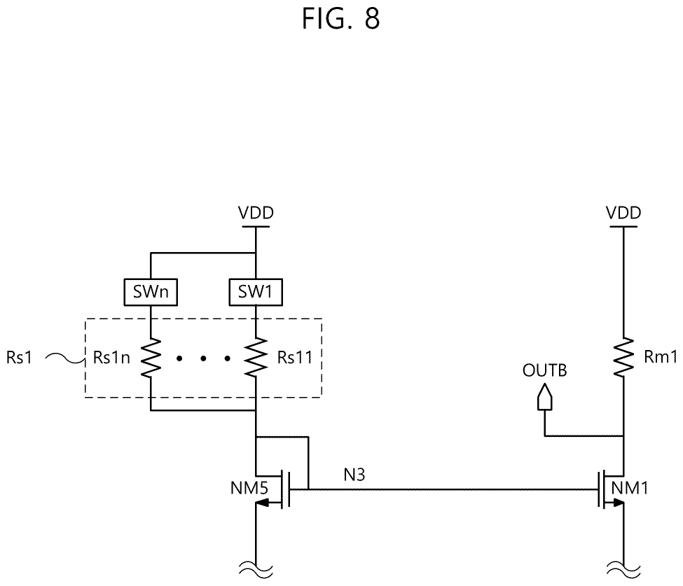

FIG. 8 is a diagram illustrating an example embodiment of a first main resistor and a first sub-resistor of FIG. 6. Referring to FIG. 8, the first sub-resistor Rs1 may include a plurality of sub-resistors Rs11 to Rs1n. Each of the plurality of sub-resistors Rs11 to Rs1n may be connected to the terminal of the power supply voltage VDD through each of a plurality of resistance switches SW1 to SWn. The plurality of sub-resistors Rs11 to Rs1n may be connected in parallel between the terminal of the power supply voltage VDD and the third node N3.

According to an example embodiment, the folded cascode amplifier 110 may vary the gain. For example, the folded cascode amplifier 110 may vary a size of the first sub-resistor Rs1 through the plurality of resistance switches SW1 to SWn. When the size of the first sub-resistor Rs1 changes, a ratio between the first main resistor Rm1 and the first sub-resistor Rs1 may change, and the gain of the amplifier including the first P-type transistor PM1 and the first N-type transistor NM1 may be changed.

Although FIG. 8 illustrates the first sub-resistor Rs1 as an example, the second sub-resistor Rs2 of FIG. 6 may also include a plurality of sub-resistors. The plurality of sub-resistors included in the second sub-resistor Rs2 may each be connected to the terminal of the power supply voltage VDD through a plurality of resistance switches. The plurality of sub-resistors included in the second sub-resistor Rs2 may be connected in parallel between the terminal of the power supply voltage VDD and the fourth node N4.

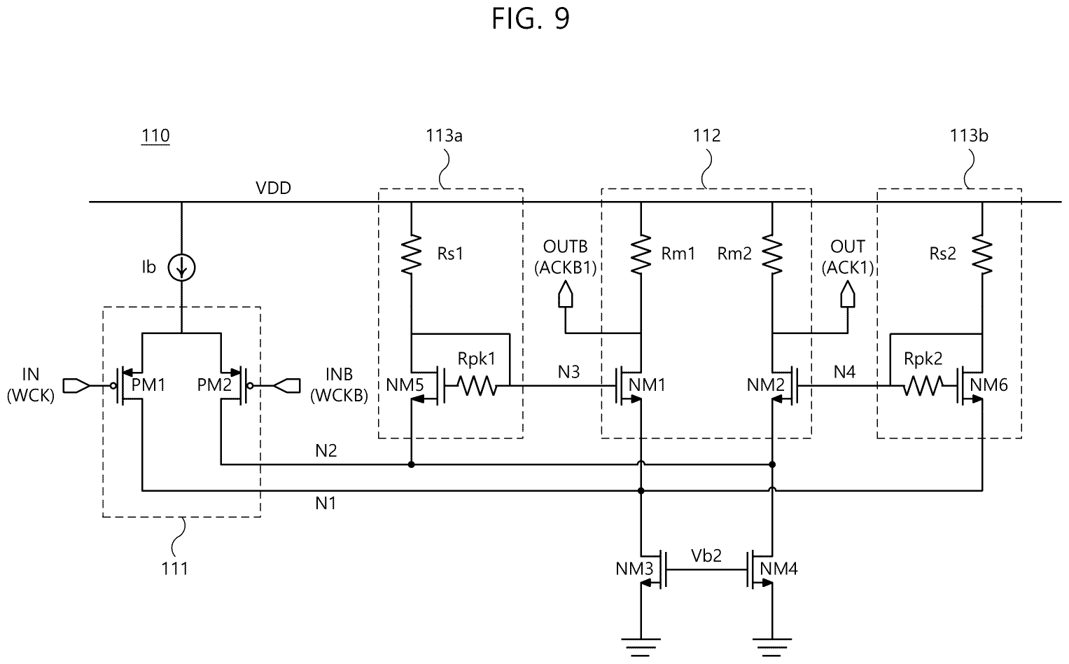

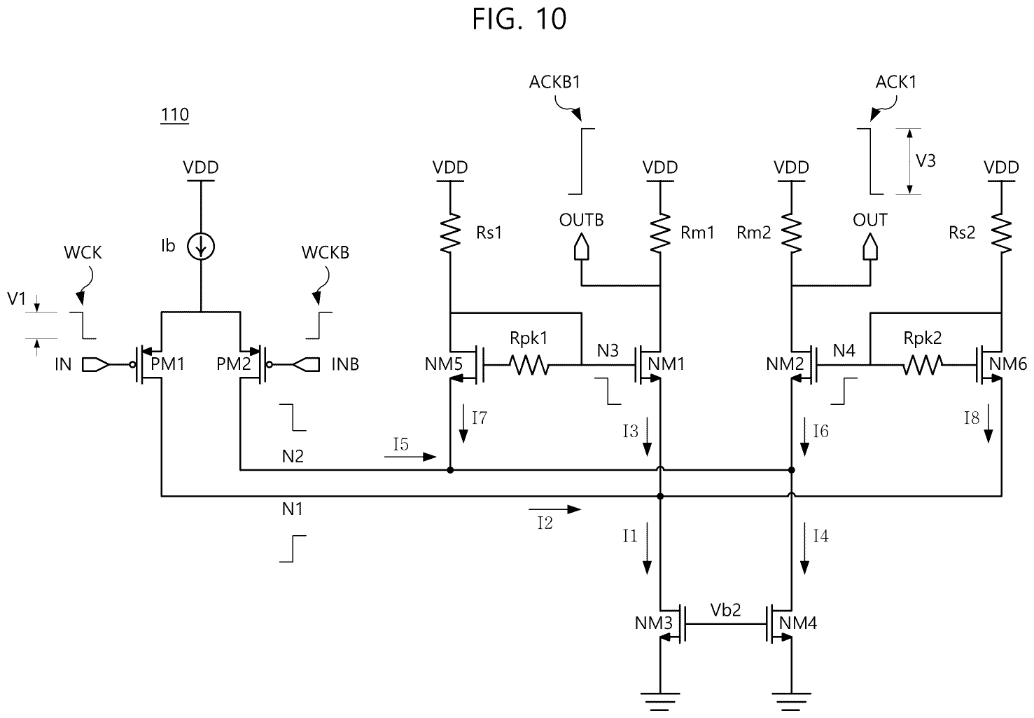

FIG. 9 is a circuit diagram illustrating another example of a folded cascode amplifier of FIG. 3. FIG. 10 is a diagram illustrating an example embodiment of an amplification operation of a folded cascode amplifier of FIG. 9. Referring to FIGS. 9 and 10, a first gain adjustment unit 113a may include a first peak resistor Rpk1. A second gain adjustment unit 113b may include a second peak resistor Rpk2.

According to an example embodiment, the folded cascode amplifier 110 may include the same or similar configuration and features as the folded cascode amplifier 110 of FIG. 6. Accordingly, descriptions of configurations and features which are the same or similar to those of the folded cascode amplifier 110 of FIG. 6 will be omitted.

According to an example embodiment, the first peak resistor Rpk1 may be connected between the gate of the fifth N-type transistor NM5 and the third node N3. A voltage of the third node N3 may change as the seventh current I7 increases or decreases. However, a parasitic capacitor may exist in the third node N3. Due to the parasitic capacitor, the voltage of the third node N3 may change more slowly than a change of the seventh current I7.

According to an example embodiment, the first peak resistor Rpk1 may cause difference between a voltage of the gate of the fifth N-type transistor NM5 and the voltage of the third node N3 for a specified time. Accordingly, the parasitic capacitor may be charged by the seventh current I7 for the specified time. After the specified time has elapsed, the voltage of the third node N3 may change quickly.

According to an example embodiment, the second peak resistor Rpk2 may be connected between the gate of the sixth N-type transistor NM6 and the fourth node N4. A voltage of the fourth node N4 may change as the eighth current I8 increases or decreases. However, a parasitic capacitor may exist in the fourth node N4. Due to the parasitic capacitor, the voltage of the fourth node N4 may change more slowly than a change of the eighth current I8.

According to an example embodiment, the second peak resistor Rpk2 may cause difference between a voltage of the gate of the sixth N-type transistor NM6 and the voltage of the fourth node N4 for a specified time. Accordingly, the parasitic capacitor may be charged by the eighth current 18 for the specified time. After the specified time has elapsed, the voltage of the fourth node N4 may change quickly.

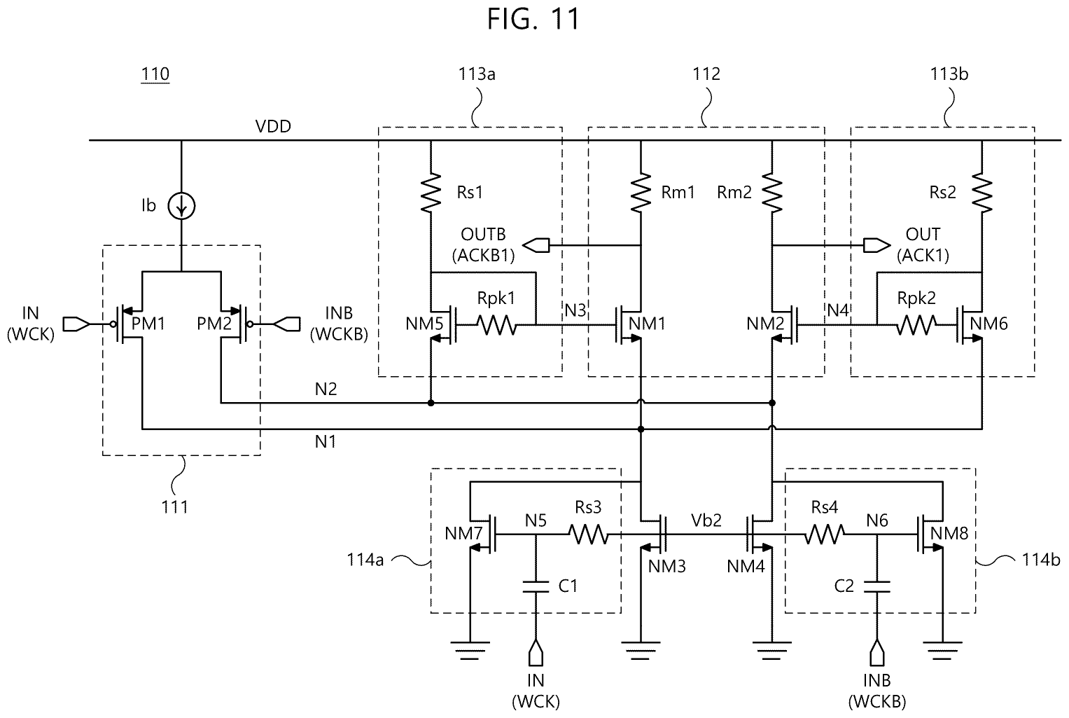

FIG. 11 is a circuit diagram illustrating another example of a folded cascode amplifier of FIG. 3. Referring to FIG. 11, the folded cascode amplifier 110 may include a first AC gain controller 114a and a second AC gain controller 114b. Herein, the first AC gain controller 114a may also be referred to as a first AC gain adjustment unit, and the second AC gain controller 114b may also be referred to a second AC gain adjustment unit.

According to an example embodiment, the folded cascode amplifier 110 may include the same or similar configuration and features as the folded cascode amplifier 110 of FIG. 9. Accordingly, descriptions of configurations and features which are the same or similar to those of the folded cascode amplifier 110 of FIG. 9 will be omitted.

According to an example embodiment, the first AC gain controller 114a may be connected between the drain and the gate of the third N-type transistor NM3. For example, the first AC gain controller 114a may include a first capacitor C1, a third sub-resistor Rs3 and/or a seventh N-type transistor NM7. The first AC gain controller 114a may increase an AC gain of an amplifier including the first P-type transistor PM1 and the first N-type transistor NM1.

According to an example embodiment, the first capacitor C1 may be connected between the input terminal IN and the fifth node N5. The third sub-resistor Rs3 may be connected between the gate of the third N-type transistor NM3 and the fifth node N5. A drain of the seventh N-type transistor NM7 may be connected to the first node N1. A gate of the seventh N-type transistor NM7 may be connected to the fifth node N5. A source of the seventh N-type transistor NM7 may be connected to the ground terminal.

According to an example embodiment, the second AC gain controller 114b may be connected between the drain and the gate of the fourth N-type transistor NM4. For example, the second AC gain controller 114b may include a second capacitor C2, a fourth sub-resistor Rs4 and/or an eighth N-type transistor NM8. The second AC gain controller 114b may increase an AC gain of an amplifier including the second P-type transistor PM2 and the second N-type transistor NM2.

According to an example embodiment, the second capacitor C2 may be connected between the complementary input terminal INB and the sixth node N6. The fourth sub-resistor Rs4 may be connected between the gate of the fourth N-type transistor NM4 and the sixth node N6. A drain of the eighth N-type transistor NM8 may be connected to the second node N2. A gate of the eighth N-type transistor NM8 may be connected to the sixth node N6. A source of the eighth N-type transistor NM8 may be connected to the ground terminal.

According to the present disclosure, it may be possible to adjust a gain of the clock amplifier circuit based on the write clock signal received from the memory controller.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A memory device comprising:
a memory cell array;
an input/output circuit configured to receive data to be stored in the memory cell array based on a write clock signal received from an external device during a write operation; and
a clock amplifier circuit configured to provide an internal clock signal to the input/output circuit by amplify the write clock signal and include a folded cascode amplifier which amplifies the write clock signal,
wherein the folded cascode amplifier is configured to amplify the write clock signal according to a gain between an input unit and an output unit, and include a gain adjustment unit which is connected to the output unit and increases the gain between the input unit and the output unit based on the write clock signal.

2. The memory device of claim 1, wherein the clock amplifier circuit comprises:
the folded cascode amplifier configured to amplify the write clock signal and output a first amplified clock signal;
a current mode logic configured to amplify the first amplified clock signal and output a second amplified clock signal; and
a CML divider configured to divide the second amplified clock signal to output the internal clock signal.

3. The memory device of claim 1, wherein the input unit comprises:
a first P-type transistor configured to include a gate to which the write clock signal is applied, a source which is connected to a first current source and a drain which is connected to a first node; and
a second P-type transistor configured to include a gate to which a complementary write clock signal is applied, a source which is connected to the first current source and a drain which is connected to a second node.

4. The memory device of claim 3, wherein the output unit comprises:
a first N-type transistor configured to include a gate which is connected to a third node, a drain which is connected to a first main resistor, and a source which is connected to the first node; and
a second N-type transistor configured to include a gate which is connected to a fourth node, a drain which is connected to a second main resistor, and a source which is connected to the second node,
wherein the drain of the first N-type transistor is configured to output a complementary amplified clock signal which is inverted and amplified from the write clock signal, and
wherein the drain of the second N-type transistor is configured to output an amplified clock signal which is inverted and amplified from the complementary write clock signal.

5. The memory device of claim 4, wherein the gain adjustment unit comprises a first gain adjustment unit and a second gain adjustment unit,
wherein the first gain adjustment unit comprises:
a third N-type transistor configured to include a source which is connected to the second node, and a drain and a gate which are connected to the third node; and
a first sub-resistor connected between a power supply voltage terminal and the third node, and
wherein the second gain adjustment unit comprises:
a fourth N-type transistor configured to include a source which is connected to the first node, and a drain and a gate which are connected to the fourth node; and
a second sub-resistor connected between the power supply voltage terminal and the fourth node.

6. The memory device of claim 4, wherein the first main resistor is connected between a power supply voltage terminal and the drain of the first N-type transistor, and
wherein the second main resistor is connected between the power supply voltage terminal and the drain of the second N-type transistor.

7. The memory device of claim 4, wherein the first node is connected to a second current source, and
wherein the second node is connected to a third current source.

8. A folded cascode amplifier circuit comprising:
a differential input unit configured to receive a first differential input signal and a second differential input signal which are complementary to each other, and output a first differential current signal in which the first differential input signal is inverted and a second differential current signal in which the second differential input signal is inverted based on a first current source;
a differential output unit configured to output a first differential amplified signal in response to the first differential current signal and output a second differential amplified signal in response to the second differential current signal; and
a gain adjustment unit configured to determine a gain between the first differential input signal and the first differential amplified signal based on the second differential current signal, and determine a gain between the second differential input signal and the second differential amplified signal based on the first differential current signal.

9. The folded cascode amplifier circuit of claim 8, wherein the differential input unit comprises:
a first P-type transistor configured to include a source which is connected to the first current source, a gate to which the first differential input signal is applied, and a drain which is connected to a second current source; and
a second P-type transistor configured to include a source which is connected to the first current source, a gate to which the second differential input signal is applied, and a drain which is connected to a third current source.

10. The folded cascode amplifier circuit of claim 8, wherein the differential output unit comprises:
a first N-type transistor configured to include a drain from which the first differential amplified signal is output, a source which is connected to a second current source, and a gate of which a voltage varies based on the second differential input signal;
a second N-type transistor configured to include a drain from which the second differential amplified signal is output, a source which is connected to a third current source, and a gate of which a voltage varies based on the first differential input signal;
a first main resistor connected between a power supply voltage terminal and the drain of the first N-type transistor; and
a second main resistor connected between the power supply voltage terminal and the drain of the second N-type transistor.

11. The folded cascode amplifier circuit of claim 10, wherein the gain adjustment unit comprises:
a third N-type transistor configured to include a drain and a gate which are connected to the gate of the first N-type transistor, and a source which is connected to the third current source;
a fourth N-type transistor configured to include a drain and a gate which are connected to the gate of the second N-type transistor, and a source which is connected to the second current source;
a first sub-resistor connected between the power supply voltage terminal and the drain of the third N-type transistor; and
a second sub-resistor connected between the power supply voltage terminal and the drain of the fourth N-type transistor.

12. The folded cascode amplifier circuit of claim 11, wherein a gain between the first differential input signal and the first differential amplified signal is configured to be proportional to a ratio between the first main resistor and the first sub-resistor.

13. The folded cascode amplifier circuit of claim 11, wherein a gain between the second differential input signal and the second differential amplified signal is configured to be proportional to a ratio between the second main resistor and the second sub-resistor.

14. The folded cascode amplifier circuit of claim 11, wherein the first sub-resistor is configured to include a plurality of first gain adjustment resistors,
wherein each of the plurality of first gain adjustment resistors is configured to be connected in parallel between the power supply voltage terminal and the drain of the third N-type transistor through each of a plurality of first switches, and
wherein a gain between the first differential input signal and the first differential amplified signal is configured to be determined based on whether the plurality of first switches are turned on.

15. The folded cascode amplifier circuit of claim 11, wherein the gain adjustment unit comprises:
a first peak resistor connected between the gate and the drain of the third N-type transistor; and
a second peak resistor connected between the gate and the drain of the fourth N-type transistor.

16. A folded cascode amplifier circuit comprising:
a first differential amplification unit configured to receive a first differential input signal and output a first differential amplified signal which is inverted and amplified from the first differential input signal;
a second differential amplification unit configured to receive a second differential input signal complementary to the first differential input signal and output a second differential amplified signal which is inverted and amplified from the second differential input signal;
a first DC gain adjustment unit configured to increase a DC gain of the first differential amplification unit based on the second differential input signal;
a second DC gain adjustment unit configured to increase a DC gain of the second differential amplification unit based on the first differential input signal;
a first AC gain adjustment unit configured to increase an AC gain of the first differential amplification unit based on the first differential input signal; and
a second AC gain adjustment unit configured to increase an AC gain of the second differential amplification unit based on the second differential input signal.

17. The folded cascode amplifier circuit of claim 16, wherein the first differential amplification unit comprises:
a first P-type transistor configured to include a source which is connected to a first current source, a gate to which the first differential input signal is applied, and a drain which is connected to a first node;
a first N-type transistor configured to include a drain which outputs the first differential amplified signal, a source which is connected to the first node, and a gate of which a voltage varies based on the second differential input signal; and
a first main resistor connected between a power supply voltage terminal and the drain of the first N-type transistor,
wherein the second differential amplification unit comprises:
a second P-type transistor configured to include a source which is connected to the first current source, a gate to which the second differential input signal is applied, and a drain which is connected to a second node;
a second N-type transistor configured to include a drain which outputs the second differential amplified signal, a source which is connected to the second node, and a gate of which a voltage varies based on the first differential input signal; and
a second main resistor connected between the power supply voltage terminal and the drain of the second N-type transistor.

18. The folded cascode amplifier circuit of claim 17, wherein the first DC gain adjustment unit comprises:
a third N-type transistor configured to include a drain and a gate which are connected to the gate of the first N-type transistor, and a source which is connected to the second node; and
a first sub-resistor connected between the power supply voltage terminal and the drain of the third N-type transistor,
wherein the second DC gain adjustment unit comprises:
a fourth N-type transistor configured to include a drain and a gate which are connected to the gate of the second N-type transistor, and a source which is connected to the first node; and
a second sub-resistor connected between the power supply voltage terminal and the drain of the fourth N-type transistor.

19. The folded cascode amplifier circuit of claim 18, further comprising:
a fifth N-type transistor configured to include a drain which is connected to the first node, a gate to which a bias voltage is applied, and a source which is connected to a ground terminal; and
a sixth N-type transistor configured to include a drain which is connected to the second node, a gate to which the bias voltage is applied, and a source which is connected to the ground terminal,
wherein the first AC gain adjustment unit comprises:
a third sub-resistor connected between the gate of the fifth N-type transistor and a fifth node;
a first capacitor connected between a first input terminal where the first differential input signal is received and the fifth node; and
a seventh N-type transistor configured to include a drain which is connected to the first node, a gate which is connected to the fifth node, and a source which is connected to the ground terminal,
wherein the second AC gain adjustment unit comprises:
a fourth sub-resistor connected between the gate of the sixth N-type transistor and a sixth node;
a second capacitor connected between a second input terminal where the second differential input signal is received and the sixth node; and
an eighth N-type transistor configured to include a drain which is connected to the second node, a gate which is connected to the sixth node, and a source which is connected to the ground terminal.

20. The folded cascode amplifier circuit of claim 18, wherein the first DC gain adjustment unit comprises a first peak resistor connected between the gate and the drain of the third N-type transistor, and
wherein the second DC gain adjustment unit comprises a second peak resistor connected between the gate and the drain of the fourth N-type transistor.
